(19) United States
(12) Patent Application Publication
(10) Pub. No.: US 2001/0008693 A1
(43) Pub. Date: Jul. 19, 2001

(54) POLYMER-INORGANIC MULTILAYER DIELECTRIC FILM

(76) Inventors: YOEL FINK, CAMBRIDGE, MA (US); EDWIN L. THOMAS, NATICK, MA (US); JOHN D. JOANNOPOULOS, BELMONT, MA (US); CHIPING CHEN, NEEDHAM, MA (US); JOSHUA N. WINN, SOMERVILLE, MA (US); SHANHUI FAN, SOMERVILLE, MA (US)

Correspondence Address: MATTHEW E CONNORS, SAMUELS GAUTHIER & STEVENS LLP, 225 FRANKLIN STREET, SUITE 3300, BOSTON,, MA, 02110

(21) Appl. No.: 09/267,854

(22) Filed: Mar. 12, 1999

Related U.S. Application Data
(60) Provisional application No. 60/078,138, filed on Mar. 16, 1998.

(51) Int. Cl. B32B 15/08; H01L 23/58

(52) U.S. Cl. 428/421; 428/521; 428/689; 428/697; 257/635; 257/642; 428/462

(57) ABSTRACT

A multilayer dielectric film structure includes a pair or plurality of materials at least one being a polymer and the other of high index of refraction inorganic material (compared to the polymer) at the wavelengths of interest. The structure is fabricated by a combination of layering techniques, one of which is used to create a layer of the polymer, the other being used to deposit the inorganic component. The assembly process yields a structure of alternating polymer and inorganic layers of high index of refraction (compared to air). The structure preferably will reflect light within a certain frequency range of any polarization and at a continuum of angles of incidence ranging from normal to oblique. In a particular embodiment of the invention, the structure includes alternating layers of a polymer, e.g., polystyrene and Tellurium.

This invention was made with funding provided by the U.S. Army under Army Grant No. DAAG55-97-1-0366, and the U.S. Air Force under Contract Nos. F49620-97-1-0325 and F49620-97-1-0385. The government has certain rights to the invention.

### PRIORITY INFORMATION

This application claims priority from provisional application Ser. No. 60/078,138 filed Mar. 16, 1998.

### BACKGROUND OF THE INVENTION

The invention relates to the field of multilayer dielectric film structures, and in particular to structures with high reflectivity characteristics.

Multilayer dielectric films are used in a wide variety of optical devices which typically utilize the frequency selective reflectivity that these films exhibit. Most of the current applications involve the reflection or transmission of light of nearly normal incidence, although grazing angle applications exist as well. The optical response of a multilayer dielectric film to light of off-normal incidence has been investigated, and is angle-of-incidence and polarization dependent.

If properly constructed, a multilayer dielectric film will have selective frequencies regions of high and low reflectivity. In general, the bandwidth of the high reflectivity region shrinks for one of the polarizations (transverse magnetic (TM), E vector in the plane of incidence) and increases for the other (transverse electric (TE), E vector transverse to the plane of incidence) as the angles of incidence become more oblique. In fact, the width of the reflective region shrinks to zero for the TM mode at the Brewster angle. Methods for reducing the angular dependence of the width of the reflective region are known and include the use of high index of refraction materials as layer components.

### SUMMARY OF THE INVENTION

The materials system or multilayer dielectric film structure of the invention includes of a pair or plurality of materials at least one being a polymer and the other of high index of refraction inorganic material (compared to the polymer) at the wavelengths of interest. The structure is fabricated by a combination of layering techniques, one of which is used to create a layer of the polymer, the other being used to deposit the inorganic component. The assembly process yields a structure of alternating polymer and inorganic layers of high index of refraction (compared to air). The structure preferably will reflect light within a certain frequency range of any polarization and at a continuum of angles of incidence ranging from normal to oblique. In a particular embodiment of the invention, the structure includes alternating layers of a polymer, e.g., polystyrene and Tellurium.

### BRIEF DESCRIPTION OF THE DRAWINGS

FIG. 1 is a simplified block diagram of an exemplary embodiment of a multilayer dielectric film structure in accordance with the invention;

FIG. 2 is a simplified block diagram of an exemplary embodiment of a multilayer dielectric film structure including alternating layers of a polystyrene polymer and tellurium in accordance with the invention; and

FIG. 3 are plots of measured (dashed) and calculated (solid) reflectance vs. wavelength for nine layer tellurium polystyrene multilayer film for the two polarizations TE and TM, and for light of 0°, 45°and 80° of incidence showing a high reflectivity region from 10-15 microns.

### DETAILED DESCRIPTION OF THE INVENTION

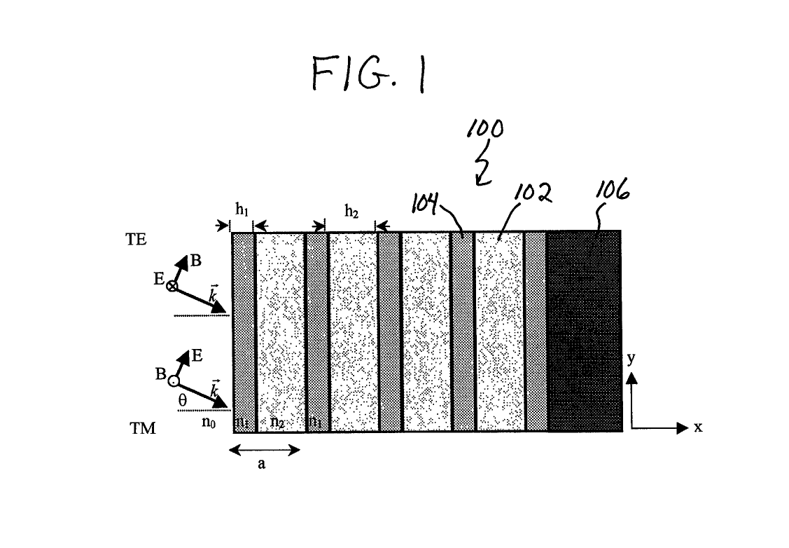

The materials system of the invention consists of one or more polymers or blends thereof, such as polyethylene, polystyrene, polyvinilidine flouride, polyvinylpyrrillidone, poly methylene (polyphenyl isocyanate) and a compatible high index of refraction component, such as tellurium, germanium and cadmium selenide (CdSe). FIG. 1 is a simplified block diagram of an exemplary embodiment of a multilayer dielectric film structure 100 in accordance with the invention. The structure 100 includes alternating layers of a first material 102 of a polymer or blend with an index of refraction n₂ and thickness h₂ and a second material 104 of a compatible high index refraction component n₁ and thickness h₁ on a substrate 106. Also in FIG. 1 are the incident wave vector k originating from the ambient medium no and the electromagnetic mode convention TM and TE.

In applications involving the use of the structure 100 for reflecting purposes, it will be appreciated that all of the individual film materials used have some degree of transparency for the wavelength range of interest. The compatibility of the materials are taken in the broadest sense subject to the proximity imposed by the structure and the particular method of assembly. For example, a polymer with traces of acetone will damage a tellurium layer. The polymers chosen will also preferably have a low degree of crystallinity and low diffusivity for the complementary component of the second material. The two (or more) components will also have chemical compatibility, i.e., the materials will not degrade when in contact with one another, physical compatibility, i.e., the materials will be able to form a well defined intimate interface, and have low interdiffusivity constants at process temperatures. For example, tellurium has a high diffusion rate in low molecular weight polyethylene at temperatures existing in a vacuum evaporation process.

The layers can be assembled on a substrate and subsequently removed or coated directly onto a surface that is part of the application. The surface should be wetted by the material that forms the first layer. The substrate can be treated with a surface modifying group for good adherence or easy removal of the assembled structure. An exemplary assembly of layers which can be subsequently removed includes a glass surface coated initially with Victawet, a sodium salt of 2-ethylhexyl acid phosphate provided by SPI Inc., and then sequentially layered with the selected materials. After assembly, the dielectric multilayer film can be removed from the Victawet coated glass substrate by using water, which will not damage a hydrophobic polymer.

Polymer layers of controlled thickness can be deposited by a variety of known techniques, for example, by spin coating a polymer layer from a solvent using a spin coating apparatus. The concentration of the solution and the spin speed can be used to control thickness. Evaporation casting can be also used to deposit polymer layers. In this technique a dilute solution of the polymer is prepared, which is then cast on the surface. The solvent subsequently evaporates and a thin film of polymer is formed.

A layer can also be formed by polymerizing a monomer in-situ, for example, styrene (65% volume), divinylbenzene (34% volume) and benzoyl peroxide (^{˜}1%) can be combined and irradiated with UV to form a heavily crosslinked polystyrene network on the surface. A polymer layer can also be deposited by heat or vacuum evaporation or by spraying onto a surface. In the assembly process, care should be taken to prevent damage of underlying layers by the presence of solvent, in general a technique which involves a minimal presence of solvent such as spin coating is preferable.

The optical response of a particular dielectric multilayer film can be predicted using the characteristic matrix method as described in Driscoll et al., Handbook of Optics, McGraw-Hill, 8-42- 8-43 (1978), incorporated herein by reference. In this method, a 2×2 unitary matrix is constructed for each layer of the structure. This matrix represents a mapping of the field components from one side of the layer to the other. To successfully predict the optical response of a multilayer film, the characteristic matrix for each layer needs to be calculated. The form of the characteristic matrix for the j^{th} layer is

$${( {m}^{g} ( θ ) )}_{j} = [ \begin{matrix}cos {β}_{j} & - \frac{i}{{p}_{j}^{g}} sin {β}_{j} \\ - {ip}_{j}^{g} sin {β}_{j} & cos {β}_{j}\end{matrix} ] ( g = TE , TM )$$

$${β}_{j} = {kh}_{j} \sqrt{{n}_{j}^{2} - snell {( θ )}^{2}}$$

$$snell ( θ ) = {n}_{0} sin {θ}_{0}$$

$${p}_{j}^{g} = \{ \begin{matrix}\sqrt{{n}_{j}^{2} - snell {( θ )}^{2}} & g = TE \\ \frac{\sqrt{{n}_{j}^{2} - snell {( θ )}^{2}}}{{n}_{j}^{2}} & g = TM\end{matrix}$$

where nⱼ is the index of refraction, hⱼ is the thickness of the j^{th} layer, θ₀is the angle between the incident wave and the normal to the surface, and no is the index of the initial medium (e.g. air). h

The matrices are then multiplied to give the film's characteristic matrix

$${M}^{g} ( θ ) = {\prod }_{j = 1}^{N} {m}_{j}^{g} ( g = TM or TE )$$

which in turn can be used to calculate the reflectivity for a given polarization and angle of incidence,

$${R}^{g} ( θ ) = {\vert \frac{( {M}_{11}^{g} ( θ ) + {M}_{12}^{g} ( θ ) {p}_{1}^{g} ) {p}_{0}^{g} - ( {M}_{21}^{g} ( θ ) + {M}_{22}^{g} ( θ ) {p}_{1}^{g} )}{( {M}_{11}^{g} ( θ ) + {M}_{12}^{g} ( θ ) {p}_{1}^{g} ) {p}_{0}^{g} + ( {M}_{21}^{g} ( θ ) + {M}_{22}^{g} ( θ ) {p}_{1}^{g} )} \vert}^{2}$$

where p^{g}₀ contains information about the index of the medium and angle of incidence on one side of the multilayer film and p^{g}₁ contains information about the index of the medium and angle of incidence on the other.

In certain embodiments, a finite periodic film consisting of alternating layers of materials with different indices of refraction is formed which exhibits high reflectivity for a particular range of frequencies determined by the respective thickness of the layers and their indices of refraction. The center frequency of the high reflectivity region at a particular angle of incidence θ is given by

$${ω}_{midgap}^{g} ( θ ) = \frac{c}{{h}_{2} \sqrt{{n}_{2}^{2} - {snell}^{2} ( θ )} + {h}_{3} \sqrt{{n}_{3}^{2} - {snell}^{2} ( θ )}} \{ {cos}^{- 1} ( - \sqrt{\frac{{Λ}^{g} ( θ ) - 1}{1 + {Λ}^{g} ( θ )}} ) + {cos}^{- 1} ( + \sqrt{\frac{{Λ}^{g} ( θ ) - 1}{1 + {Λ}^{g} ( θ )}} ) \}$$

The extent in frequency of this region for a given angle of incidence θ and at a particular polarization g is given by

$${Δω}^{g} ( θ ) = \frac{2 c}{{h}_{2} \sqrt{{n}_{2}^{2} - {snell}^{2} ( θ )} + {h}_{3} \sqrt{{n}_{3}^{2} - {snell}^{2} ( θ )}} \{ {cos}^{- 1} ( - \sqrt{\frac{{Λ}^{g} ( θ ) - 1}{1 + {Λ}^{g} ( θ )}} ) + {cos}^{- 1} ( + \sqrt{\frac{{Λ}^{g} ( θ ) - 1}{1 + {Λ}^{g} ( θ )}} ) \}$$

$$where$$

$${Λ}^{g} ( θ ) = \frac{1}{2} ( \frac{{p}_{2}^{g}}{{p}_{3}^{g}} + \frac{{p}_{3}^{g}}{{p}_{2}^{g}} )$$

n₂, n₃are the indices of refraction of the two layers repeated throughout the structure, h₂, h₃are their thickness, and c is the speed of light in vacuum.

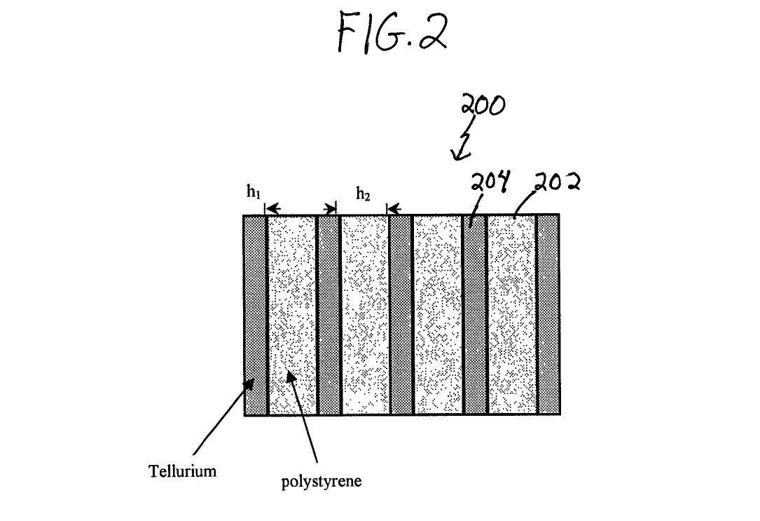

FIG. 2 is a simplified block diagram of an exemplary embodiment of a multilayer dielectric film structure 200 in accordance with the invention. The structure 200 includes alternating layers of a polystyrene (PS) polymer 202 and tellurium (Te) 204. The polymer exhibits low loss in the 2.5-25 micron range, has excellent mechanical properties, and forms continuous ultra smooth films. The index of refraction for the polymer is very close to 1.5 across the entire frequency range of interest.

Tellurium is an element with low infrared (IR) absorption and high index of refraction in the 2.5-25 micron wavelength region. It is chemically stable, does not oxidize easily, and has low diffusivity in polystyrene. In addition, tellurium adheres well to polymers and forms consistent layers from vacuum evaporation which are environmentally stable. Tellurium films are able to conduct moisture and small solvent molecules, and may be considered a “breathable” material. It has a low latent heat of evaporation ^{˜}105 kJ/mol compared with germanium 327 kJ/mol and a relatively low boiling point (990° C.) which allows for low temperature processing and minimizes heat damage. Another benefit of the small latent heat content is low diffusivities upon condensation since relatively little heat is released. Both the polymer and tellurium are non-carcinogenic and are non-toxic in the bulk form (i.e., no dust).

The assembly method includes spin coating at 1000 RPM onto a NaCl window (Wilmad 25 mm). The solution was 10% weight of polystyrene (GoodYear molecular weight=120k) in toluene. An additional evaporation stage at room temperature for 3 hours followed the spin coating to ensure complete solvent removal.

The tellurium (Strem Chemicals broken ingots) was evaporated in a vacuum evaporator (Ladd model 30000) under a 5×10⁻⁶ Torr vacuum and at a current of 7 Amps, which yielded a maximum evaporation rate of 3 angstrom per second. The film thickness and evaporation rate was monitored in-situ using a Crystal Film Thickness Monitor (Sycon Instruments model STM100), and final film thickness was determined with a profilometer (Tencor model P10). The tellurium and polystyrene films were deposited sequentially leading to the formation of a nine layer film as follows: Te/PS/Te/PS/Te/PS/Te/PS/Te.

The optical response of this particular multilayer film was designed to have a high reflectivity region in the 10-15 micron range by choosing the appropriate quarter-wave thicknesses such that n_{Te}h_{Te}=n_{PS}h_{PS}=12.5/4 at angles of incidence ranging from 0 to 80 degrees at least. The optical response was predicted using the method outlined above and measured using a Fourier Transform Infra Red Spectrometer (Nicolet 860) fitted with a polarizer (ZnS SpectraTech) and an angular reflectivity stage (VMAX by SpectraTech).

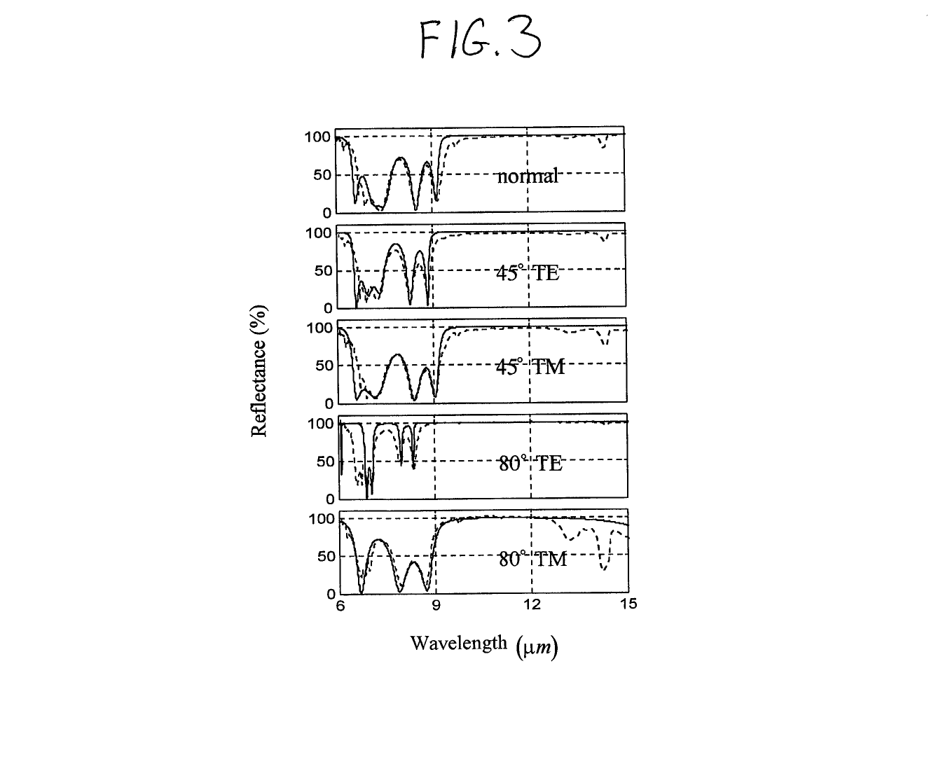

A comparison of the predicted and measured optical response is presented in the figures below. FIGS. 3 are plots of measured (solid) and calculated (dashed) reflectance vs. wavelength for nine layer tellurium polystyrene multilayer film for the two polarizations TE and TM (d,e,f), and for 0°, 45° and 80° angles of incidence showing a high reflectivity region from 10-15 microns.

The measured and predicted optical response of the exemplary nine layer tellurium polystyrene film of FIG. 2 is shown in FIG. 3 for normal incidence, and for light incident at 30° for TE and TM modes. Where the electric field is perpendicular to the plane defined by the wave vector and the normal to the surface in the TM mode and in the plane for the TE mode.

A high reflectivity region is predicted and observed for normal incidence light extending from 10-20 microns. The slope of the boundaries enclosing this region can be increased by increasing the number of layers. As the angle of incidence is increased, the qualitative behavior of the two modes differ. The width of the high reflectivity region for the TE mode increases at increasingly oblique angles of incidence. The width of this same region for the TM mode shrinks, however, for the materials illustrated in the exemplary embodiment does not disappear in fact at 80° incidence, the width is still larger than 3 microns.

In addition to the reflectance due to the stratified structure, absorption is also present. In fact, polymers are known to have distinct absorption bands in the IR corresponding to the excitation of vibrational modes of different bonds. The dip located in the vicinity of 14 microns is an example of a known absorption band for polystyrene (Aldrich Library of FTIR spectra). It will be appreciated that this absorption peak grows at larger angles of incidence reflecting the increasing path of the light in the polystyrene layer. It is also more pronounced for the TM mode. The total thickness of the exemplary seven layer device is approximately 9 microns.

Although the present invention has been shown and described with respect to several preferred embodiments thereof, various changes, omissions and additions to the form and detail thereof, may be made therein, without departing from the spirit and scope of the invention.

What is claimed is:

1. A multilayer dielectric film structure comprising a plurality of alternating layers of polymeric material and inorganic material.

2. The structure of claim 1, wherein said alternating layers are transparent for predetermined wavelength ranges.

3. The structure of claim 1, wherein said inorganic material comprises non-metallic material.

4. The structure of claim 1, wherein said layers of polymeric material comprise at least one polymer.

5. The structure of claim 1, wherein said layers of polymeric material comprise a varying plurality of polymers.

6. The structure of claim 1, wherein said layers of polymeric material comprise polymeric blends.

7. The structure of claim 1, wherein said layers of said inorganic material comprise at least one inorganic material.

8. The structure of claim 1, wherein said layers of said inorganic material comprise a varying plurality of inorganic materials.

9. The structure of claim 1, wherein a contrast of index of refraction exists between each of said alternating layers.

10. The structure of claim 1, wherein each of said alternating layers comprises at least one polymeric material layer and inorganic material layer, respectively.

11. The structure of claim 1, wherein said polymeric material includes polyethylene, polystyrene, polyvinilidine fluoride, or polyvinylpyrrillidone.

12. The structure of claim 1, wherein said inorganic material includes tellurium, germanium, or cadmium selenide.

13. The structure of claim 1, wherein said polymeric material comprises polystyrene and said inorganic material comprises tellurium.

14. The structure of claim 1, wherein said inorganic material comprises a transparent metallic inorganic material.

15. The structure of claim 1, wherein said structure is highly reflective within a predetermined frequency range of any polarization and at a continuum of angles of incidence ranging from normal to oblique.

16. The structure of claim 1, wherein said structure comprises a coating.

17. A method of fabricating a multilayer dielectric film structure comprising:
providing a surface layer;
depositing a first layer of one of a polymeric material or an inorganic material on said surface layer;
depositing a second layer of the other of a polymeric material or an inorganic material on said first layer; and
alternately depositing a subsequent sequence of said first and second layers on said second layer.

18. The method of claim 17, wherein said surface layer comprises a wetted surface.

19. The method of claim 17, wherein said surface layer comprises a substrate from which the sequence of first and second layers are removed.

20. The method of claim 17, wherein the alternate sequence of first and second layers is provided as a coating.

21. The method of claim 17, wherein the alternate sequence of said first and second layers are transparent for predetermined wavelength ranges.

22. The method of claim 17, wherein said inorganic material comprises non-metallic material.

23. The method of claim 17, wherein the layers of polymeric material comprise at least one polymer.

24. The method of claim 17, wherein the layers of polymeric material comprise a varying plurality of polymers.

25. The method of claim 17, wherein the layers of polymeric material comprise polymeric blends.

26. The method of claim 17, wherein the layers of said inorganic material comprise at least one inorganic material.

27. The method of claim 17, wherein the layers of said inorganic material comprise a varying plurality of inorganic materials.

28. The method of claim 17, wherein a contrast of index of refraction exists between each of the alternating layers.

29. The method of claim 17, wherein each of the alternating layers comprises at least one polymeric material layer and inorganic material layer, respectively.

30. The method of claim 17, wherein said polymeric material includes polyethylene, polystyrene, polyvinilidine fluoride, or polyvinylpyrrillidone.

31. The method of claim 17, wherein said inorganic material includes tellurium, germanium, or cadmium selenide.

32. The method of claim 17, wherein said polymeric material comprises polystyrene and said inorganic material comprises tellurium.

33. The method of claim 17, wherein said inorganic material comprises a transparent metallic inorganic material.

34. The method of claim 17, wherein said structure is highly reflective within a predetermined frequency range of any polarization and at a continuum of angles of incidence ranging from normal to oblique.

35. A multilayer dielectric film reflector comprising a plurality of alternating layers of polymeric material and Tellurium.

36. The reflector of claim 35, wherein said polymeric material comprises polystyrene.

37. The reflector of claim 35, wherein said layers of polymeric material comprise at least one polymer.

38. The reflector of claim 35, wherein said layers of polymeric material comprise a varying plurality of polymers.

39. The reflector of claim 35, wherein said reflector exhibits high reflectivity characteristics for a predetermined range of frequencies for incident electromagnetic energy at a plurality of incident angles and any polarization.

40. The reflector of claim 39, wherein said range of frequencies comprises a range from about 2.5 μm to about 25 μm.

41. The reflector of claim 40, wherein said range of frequencies comprises a range from about 10 μm to about 15 μm.

42. The reflector of claim 35, wherein the total number (N) of layers, the layer thickness (h₂,h₃) and corresponding indices of refraction (n₂,n₃) are determined to provide a reflectivity R^{g}(θ) of a predetermined value for a particular frequency, polarization g and angle of incidence θ in accordance with
$${R}^{g} ( θ ) = {\vert \frac{( {M}_{11}^{g} ( θ ) + {M}_{12}^{g} ( θ ) {p}_{1}^{g} ) {p}_{0}^{g} - ( {M}_{21}^{g} ( θ ) + {M}_{22}^{g} ( θ ) {p}_{1}^{g} )}{( {M}_{11}^{g} ( θ ) + {M}_{12}^{g} ( θ ) {p}_{1}^{g} ) {p}_{0}^{g} + ( {M}_{21}^{g} ( θ ) + {M}_{22}^{g} ( θ ) {p}_{1}^{g} )} \vert}^{2}$$
$$where$$
$${M}^{g} ( θ ) = {\prod }_{j = 1}^{N} {m}_{j}^{g} ( g = TM or TE )$$
$${and \\ ( {m}^{g} ( θ ) )}_{j} = [ \begin{matrix}cos {β}_{j} & - \frac{i}{{p}_{j}^{g}} sin {β}_{j} \\ - {ip}_{j}^{g} sin {β}_{j} & cos {β}_{j}\end{matrix} ] ( g = TE , TM )$$
$${β}_{j} = {kh}_{j} \sqrt{{n}_{j}^{2} - snell {( θ )}^{2}}$$
$$snell ( θ ) = {n}_{0} sin {θ}_{0}$$
$${p}_{j}^{g} = \{ \begin{matrix}\sqrt{{n}_{j}^{2} - snell {( θ )}^{2}} & g = TE \\ \frac{\sqrt{{n}_{j}^{2} - snell {( θ )}^{2}}}{{n}_{j}^{2}} & g = TM\end{matrix}$$
where nⱼ is the index of refraction, hⱼ is the thickness of the j^{th} layer, θ₀ is the angle between the incident wave and the normal to the surface, and n₀ is the index of the initial medium.

43. The reflector of claim 1, wherein said reflector comprises a coating.
